(19) United States
(12) Patent Application Publication
(10) Pub. No.: US 2012/0044103 A1
(43) Pub. Date: Feb. 23, 2012

(54) PARALLEL INTERPOLATION A/D CONVERTER AND DIGITAL EQUALIZER

(75) Inventors: Rie Kaihara, Kyoto (JP); Masakazu Shigemori, Osaka (JP); Youichi Ogura, Osaka (JP); Junichi Naka, Osaka (JP); Tsuyoshi Matsushita, Osaka (JP)

(73) Assignee: PANASONIC CORPORATION, OSAKA (JP)

(21) Appl. No.: 13/287,617

(22) Filed: Nov. 2, 2011

Related U.S. Application Data
(63) Continuation of application No. PCT/JP2010/002222, filed on Mar. 26, 2010.

(30) Foreign Application Priority Data
May 26, 2009 (JP) 2009-126800

(51) Int. Cl. H03M 1/36

(52) U.S. Cl. 341/159

(57) ABSTRACT

A parallel interpolation A/D converter includes a reference voltage generation circuit configured to generate (m+1) different reference voltages VR₁-VRₘ₊₁, where m is a positive integer, and VR₁<VR₂, . . . , <VRₘ<VRₘ₊₁, a differential amplifier series including (m+1) differential amplifiers A₁-Aₘ₊₁ configured to amplify voltage differences between the reference voltages VR₁-VRₘ₊₁ and an input signal voltage, and an operation circuit including a plurality of comparator circuits configured to receive output voltage sets generated by the respective differential amplifiers. The number of comparator circuits varies depending on the value k of the reference voltage VRₖ, where k is an integer of 2≦k≦m+1.

### CROSS-REFERENCE TO RELATED APPLICATIONS

This is a continuation of PCT International Application PCT/JP2010/002222 filed on Mar. 26, 2010, which claims priority to Japanese Patent Application No. 2009-126800 filed on May 26, 2009. The disclosures of these applications including the specifications, the drawings, and the claims are hereby incorporated by reference in their entirety.

### BACKGROUND

The present disclosure relates to parallel interpolation analog-to-digital (A/D) converters and digital equalizers.

In recent years, the speed and density of information communication devices, such as hard disk devices, optical disk devices, communication devices, etc., have been increasing. When a signal processing device is fabricated as a system-on-a-chip (SOC), there is the following significant problem. Analog circuits require considerably large areas and large power consumption compared to digital circuits. Therefore, there is a demand for increasing replacement of analog signal processing with digital signal processing to reduce analog circuits.

To meet this demand, a small-size and low-power consumption A/D converter which precisely converts an analog signal into a digital signal is required.

There are various types of A/D converters, such as successive approximation, pipeline, delta-sigma, etc. As an A/D converter which quickly converts a radio frequency (RF) signal into a digital signal in the field of information communication, a parallel interpolation A/D converter is known, which advantageously performs a high-speed operation (see Japanese Patent No. 3904495).

On the other hand, as digital signal processing is dominating, there is also a strong demand for a higher resolution of the A/D converter. Resolution may be enhanced by increasing the number of bits representing a digitized signal. In this case, however, the circuit area and power consumption disadvantageously increase in proportion to the number of bits. Therefore, there is a known digital equalizer which addresses the above problem using an entire analog-digital hybrid system (see Japanese Patent No. 4230937).

There is also a known A/D converter which converts an important range of an input analog signal into a high-resolution digital signal and a range within which a smaller amount of information is carried into a low-resolution digital signal (see Japanese Patent Publication No. 2008-263613).

The parallel interpolation A/D converter of Japanese Patent No. 3904495 has the advantage of being capable of A/D conversion at a higher speed than those of the successive approximation A/D converter, the pipeline A/D converter, etc., and the disadvantage that as the resolution is increased, the number of differential amplifier circuits and the number of comparator circuits increase, leading to an increase in the circuit area and power consumption.

The digital equalizer of Japanese Patent No. 4230937 has nonlinear analog-to-digital conversion characteristics, and therefore, requires a complicated unit which calculates the offset amount and amplitude value of a signal. Therefore, it is difficult to increase the speed of the digital equalizer.

In the A/D converter of Japanese Patent Publication No. 2008-263613, for example, when a digital filter such as an adaptive equalization etc. performs a convolution on a high-density RF waveform, distortions occur, so that waveform equalization cannot be normally achieved.

The present disclosure describes implementations of a parallel interpolation A/D converter in which the increase of circuit area and power consumption due to an increased resolution can be reduced, and a digital equalizer including the A/D converter.

### SUMMARY

A first example parallel interpolation A/D converter according to the present disclosure includes a reference voltage generation circuit configured to generate (m+1) different reference voltages VR₁-VRₘ₊₁, where m is a positive integer, and VR₁<VR₂, . . . , <VRₘ<VRₘ₊₁, a differential amplifier series including (m+1) differential amplifiers A₁-Aₘ₊₁ configured to amplify voltage differences between the reference voltages VR₁-VRₘ₊₁ and an input signal voltage, respectively, to generate output voltage sets, where the output voltage set of each of the differential amplifiers A₁-Aₘ₊₁ includes a non-inverted output voltage and an inverted output voltage which are complementary to each other, and a plurality of comparator circuits configured to receive the output voltage sets of the respective differential amplifiers. Each of the comparator circuits receives a first and a second output voltage set of the plurality of output voltage sets, the first output voltage set including a first non-inverted output voltage and a first inverted output voltage and output from the differential amplifier Aₖ which receives the reference voltage VRₖ, and the second output voltage set including a second non-inverted output voltage and a second inverted output voltage and output from the differential amplifier Aₖ₋₁ which receives the reference voltage VRₖ₋₁, where k is an integer of 2≦k≦m+1, compares a difference of the first output voltage set with a difference of the second output voltage set, and based on a result of the comparison, outputs a digital signal. The number of the comparator circuits varies depending on the value k of the reference voltage VRₖ. As a result, by increasing circuit variation resistance so that analog signal components containing more important information can be precisely converted and decreasing the circuit variation resistance for less important information components, the circuit area and power consumption can be reduced.

A second example parallel interpolation A/D converter according to the present disclosure includes a reference voltage generation circuit configured to generate (m+1) different reference voltages VR₁-VRₘ₊₁, where m is a positive integer, and VR₁<VR₂, . . . , <VRₘ<VRₘ₊₁, a differential amplifier series including (m+1) differential amplifiers A₁-Aₘ₊₁ configured to amplify voltage differences between the reference voltages VR₁-VRₘ₊₁ and an input signal voltage, respectively, to generate output voltage sets, where the output voltage set of each of the differential amplifiers A₁-Aₘ₊₁ includes a non-inverted output voltage and an inverted output voltage which are complementary to each other, and a plurality of comparator circuits configured to receive the output voltage sets of the respective differential amplifiers. Each of the comparator circuits receives a first and a second output voltage set of the plurality of output voltage sets, the first output voltage set including a first non-inverted output voltage and a first inverted output voltage and output from the differential amplifier Aₖ which receives the reference voltage VRₖ, and the second output voltage set including a second non-inverted output voltage and a second inverted output voltage and output from the differential amplifier Aₖ₋₁ which receives the reference voltage VRₖ₋₁, where k is an integer of 2≦k≦m+1, compares a difference of the first output voltage set with a difference of the second output voltage set, and based on a result of the comparison, outputs a digital signal. The differential amplifiers have different gains. As a result, by increasing circuit variation resistance so that analog signal components containing more important information can be precisely converted and decreasing the circuit variation resistance for less important information components, the circuit area and power consumption can be reduced.

In the second example parallel interpolation A/D converter, the comparator circuits may correct the gains of the differential amplifiers. As a result, by using the comparator circuits which uniformly interpolate the outputs of the differential amplifiers having different gains, it is possible to reduce or eliminate a step which occurs in a portion of resolutions of the second example parallel interpolation A/D converter.

The second example parallel interpolation A/D converter may further include a controller configured to control the gains of the differential amplifiers. As a result, the gain can be changed depending on the quality of the circuit or the like, whereby the A/D converter can operate under optimal conditions, resulting in a reduction in power consumption.

In this case, the second example parallel interpolation A/D converter may further include a monitoring section configured to monitor system performance. The gains of the differential amplifiers may be controlled based on information from the monitoring section. As a result, the gain can be changed depending on the operating state of the system, whereby the A/D converter can operate under optimal conditions, resulting in a reduction in power consumption.

In the second example parallel interpolation A/D converter, the gain of each of the differential amplifiers may be determined by a size of a transistor included in each of the differential amplifiers. As a result, a circuit for adjusting the gain is no longer required, whereby the number of circuits can be reduced.

A first example digital equalizer includes the first example parallel interpolation A/D converter configured to convert an analog signal into a digital signal, and a digital equalization section configured to perform waveform equalization on the digital signal output from the parallel interpolation A/D converter. As a result, waveform equalization can be more precisely performed on signal components containing necessary information. Moreover, the increase of circuit size and power consumption in proportion to the resolution of the A/D converter can be reduced.

A second example digital equalizer includes the second example parallel interpolation A/D converter configured to convert an analog signal into a digital signal, and a digital equalization section configured to perform waveform equalization on the digital signal output from the parallel interpolation A/D converter. As a result, waveform equalization can be more precisely performed on signal components containing necessary information. Moreover, the increase of circuit size and power consumption in proportion to the resolution of the A/D converter can be reduced.

As described above, according to the A/D converter of the present disclosure, the circuit variation resistance is increased so that analog signal components containing more important information can be precisely converted, and the circuit variation resistance is decreased for less important information components, whereby the circuit area and power consumption can be reduced while keeping the uniformity of resolution.

### BRIEF DESCRIPTION OF THE DRAWINGS

FIG. 1 is a diagram showing a configuration of a parallel interpolation A/D converter according to a first embodiment of the present disclosure.

FIG. 2 is a diagram showing an example of the circuit area and power consumption reduction effect of the first embodiment of the present disclosure.

FIG. 3 is a diagram showing a configuration of a parallel interpolation A/D converter according to a second embodiment of the present disclosure.

FIG. 4 is a diagram showing an example differential amplifier used in the parallel interpolation A/D converter.

FIG. 5 is a diagram showing an example comparator circuit used in the parallel interpolation A/D converter.

FIG. 6 is a diagram showing paths of input signals of a comparator circuit and a threshold.

FIG. 7 is a diagram showing paths of input signals of a comparator circuit and a threshold when adjacent differential amplifiers have different gains.

FIG. 8 is a diagram showing a configuration of a parallel interpolation A/D converter according to a third embodiment of the present disclosure.

FIG. 9 is a diagram showing a configuration of a parallel interpolation A/D converter in an application of the third embodiment of the present disclosure.

FIG. 10 is a diagram showing a configuration of a digital equalizer according to a fourth embodiment of the present disclosure.

### DETAILED DESCRIPTION

Embodiments of the present disclosure will be described hereinafter with reference to the accompanying drawings. Note that like parts are indicated by like reference characters.

### First Embodiment

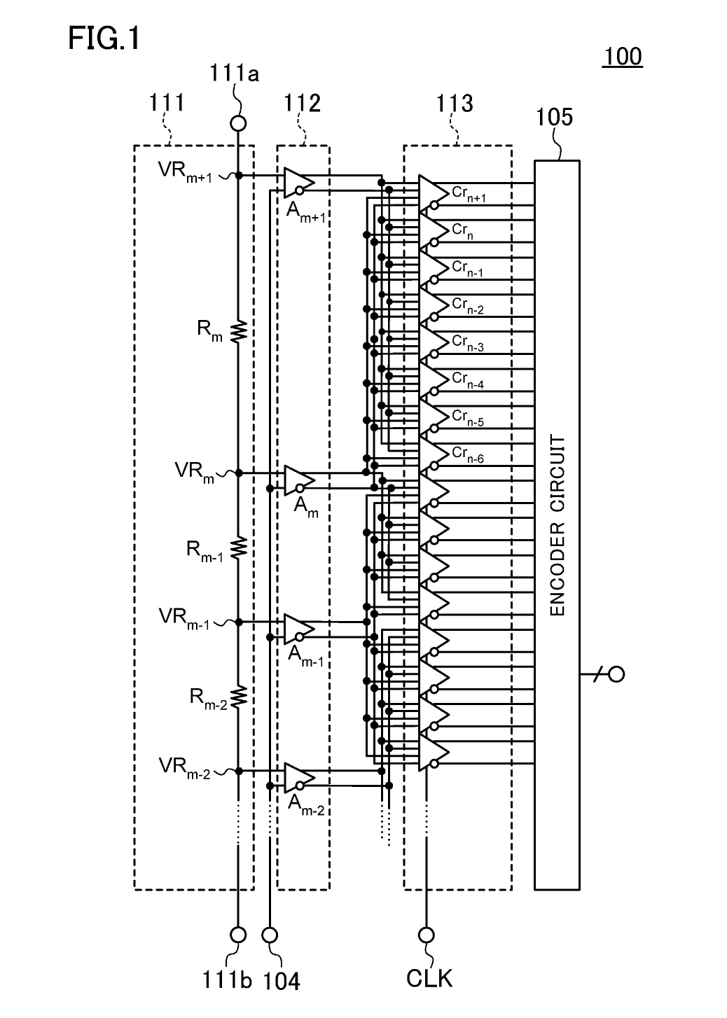

FIG. 1 is a diagram showing a configuration of an A/D converter 100 according to a first embodiment of the present disclosure. The A/D converter 100 includes a reference voltage generation circuit 111, a series of differential amplifiers (differential amplifier series) 112, and an operation circuit 113. The A/D converter 100 may further include an encoder circuit 105. The reference voltage generation circuit 111 generates a plurality of reference voltages VR₁-VRₘ₊₁ (m is a positive integer). FIG. 1 shows only an upper portion of the input dynamic range of the A/D converter 100. The differential amplifier series 112 includes (m+1) differential amplifiers A₁-Aₘ₊₁, and amplifies voltage differences between the respective reference voltages VR₁-VRₘ₊₁ and an analog signal voltage Ain input through an analog signal voltage input terminal 104, to generate a plurality of output voltage sets. Here, each output voltage set includes a non-inverted output voltage and an inverted output voltage which are complementary to each other. The operation circuit 113 receives the output voltage sets, and operates based on a clock signal CLK, for example. Here, instead of the clock signal CLK, the operation circuit 113 may be controlled using any other signal based on which the operation circuit 113 can operate at predetermined timings. The operation circuit 113 includes (n+1) comparator circuits Cr₁-Crₙ₊₁ (n is a positive integer). The comparator circuits Cr₁-Crₙ₊₁ each have four inputs. The non-inverted and inverted output voltages included in the output voltage sets from the differential amplifiers A₁-Aₘ₊₁ are input directly to the comparator circuits Cr₁-Crₙ₊₁.

The comparator circuits Cr₁-Crₙ₊₁ each have an input transistor section and a positive feedback section. Although the comparator circuit is here assumed to be formed of transistors, the comparator circuit may be formed of resistors, capacitors, and the like. The positive feedback section operates based on the clock signal CLK.

The encoder circuit 105 encodes the result of comparison (digital signal) to generate a digital data signal.

Each of the above parts will be described in detail hereinafter.

The reference voltage generation circuit 111 includes m resistors R₁-Rₘ connected together in series. A high-potential reference voltage 111a and a low-potential reference voltage 111b are applied to the opposite ends of the resistor series. As a result, a voltage between the high-potential reference voltage 111a and the low-potential reference voltage 111b is divided to generate the reference voltages VR₁-VRₘ₊₁.

The differential amplifiers A₁-Aₘ₊₁ of the differential amplifier series 112 each have two input terminals. The input analog signal voltage Ain is input to one of the two input terminals, and a corresponding one of the reference voltages VR₁-VRₘ₊₁ is input to the other input terminal. As a result, a plurality of output voltage sets (e.g., a first output voltage set, a second output voltage set, etc.) are output. Here, the output voltage sets each include a non-inverted output voltage V₁-Vₘ₊₁ and an inverted output voltage VB₁-VBₘ₊₁ which are complementary to each other.

In each of the comparator circuits Cr₁-Crₙ₊₁ of the operation circuit 113, the input transistor section performs a predetermined weighted calculation to determine a threshold voltage Vtn, compares a difference between a first non-inverted output voltage and a first inverted output voltage with a difference between a second non-inverted output voltage and a second inverted output voltage, and outputs the result of the comparison to the positive feedback section. Here, the first non-inverted output voltage and the first inverted output voltage are included in the first output voltage set, and the second non-inverted output voltage and the second inverted output voltage are included in the second output voltage set.

The positive feedback section, when the clock signal CLK is at a predetermined level, amplifies the comparison result output from the input transistor section, holds the amplified comparison result, and outputs the amplified comparison result as a digital signal to the encoder circuit 105. For example, the digital signal has a high level or a low level, depending on the comparison result.

In FIG. 1 showing the configuration of the first embodiment, when the reference voltage is VRₖ (k is an integer of 2≦k≦m+1), the number of comparator circuits is eight for k=m+1 and four for k=m. The present disclosure is not limited to this. A feature of the present disclosure is that the number of comparator circuits varies depending on the value k. The number of comparator circuits may be 2^{t} (t is an integer) for each value k.

Next, the advantage that the number of comparator circuits varies depending on the value k will be described. Here, it is assumed that signal components within ±25% from the center of the input dynamic range (100%) of the A/D converter 100 contain more important information.

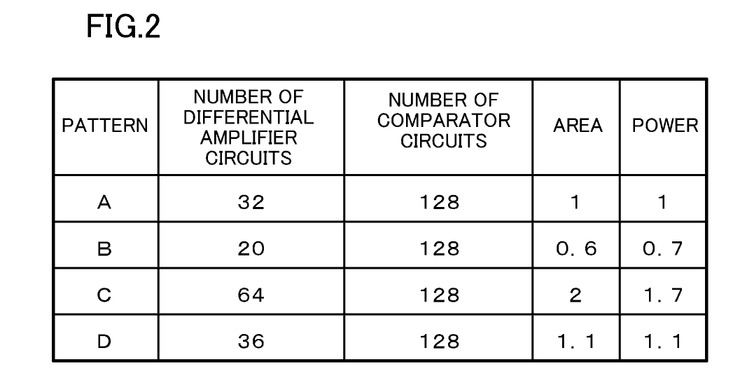

FIG. 2 shows the number of differential amplifier circuits, number of comparator circuits, circuit area, and power consumption of a 7-bit A/D converter for comparison of a case (pattern A) where the number of comparator circuits is four (2-bit interpolation) for all possible values k and a case (pattern B) where the number of comparator circuits is four (2-bit interpolation) within ±25% from the center and the number of comparator circuits is 16 (4-bit interpolation) for the rest of the input dynamic range. The values of circuit area and power consumption are relative values, assuming that those for the pattern A are one. Note that it is assumed that the circuit area of a differential amplifier circuit is 20 times as large as that of a comparator circuit, and the power consumption of a differential amplifier is 10 times as large as that of a comparator circuit. The circuit area and power consumption vary depending on a difference in the circuit configuration or manufacturing process.

As shown in FIG. 2, the circuit area is reduced by 40% and the power consumption is reduced by 30% in the pattern B compared to the pattern A. Note that as the number of comparator circuits used increases, the reduction in circuit area and power consumption increases.

Next, in the case of a system in which a higher-density input signal is processed, 2-bit interpolation is performed for the pattern A, but in order to reduce an influence of variations and precisely convert an analog signal to a digital signal, the number of comparator circuits (i.e., the number of interpolation bits) may need to be reduced.

A pattern C shows a case where the number of comparator circuits is one for all possible values k. A pattern D shows a case where the number of comparator circuits is two (1-bit interpolation) within ±25% from the center and the number of comparator circuits is 16 (4-bit interpolation) for the rest of the input dynamic range.

Compared to the pattern A, the circuit area is increased by a factor of 2 and the power consumption is increased by a factor of 1.7 in the case where the number of interpolation bits is changed from 2 to 1. The circuit area and power consumption of the pattern D are almost the same as those of the pattern A.

Note that resistance to variations can be enhanced by adding a correction section for the comparator circuit. There is a tradeoff between the circuit area of the correction section and the resistance to variations of the A/D converter. Because the area of a digital circuit in microfabrication is considerably small, the digital circuit can be produced without a very large increase in the area by using the correction section employing a digital correction technique.

As described above, in the first embodiment of the present disclosure, the number of comparator circuits is set based on the value k. Therefore, by enhancing the circuit variation resistance so that analog signal components containing more important information can be precisely converted, and reducing the circuit variation resistance for less important information components, the circuit area and power consumption can be reduced while keeping the uniformity of resolution.

### Second Embodiment

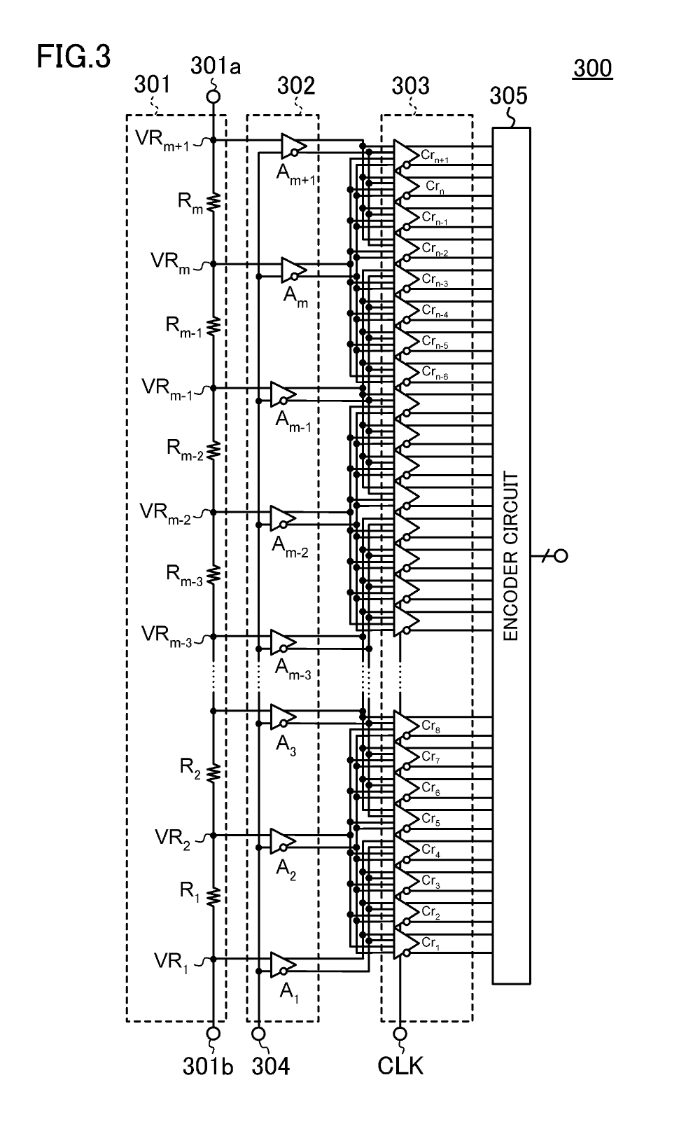

FIG. 3 is a diagram showing a configuration of an A/D converter 300 according to a second embodiment of the present disclosure. The A/D converter 300 includes a reference voltage generation circuit 301, a series of differential amplifiers (differential amplifier series) 302, and an operation circuit 303. The A/D converter 300 may further include an encoder circuit 305. The reference voltage generation circuit 301 generates a plurality of reference voltages VR₁-VRₘ₊₁ (m is a positive integer). The differential amplifier series 302 includes (m+1) differential amplifiers A₁-Aₘ₊₁, and amplifies voltage differences between the respective reference voltages VR₁-VRₘ₊₁ and an analog signal voltage Ain input through an analog signal voltage input terminal 304, to generate a plurality of output voltage sets. Here, each output voltage set includes a non-inverted output voltage and an inverted output voltage which are complementary to each other. The operation circuit 303 receives the output voltage sets, and operates based on a clock signal CLK, for example. Here, instead of the clock signal CLK, the operation circuit 303 may be controlled using any other signal based on which the operation circuit 303 can operate at predetermined timings. The operation circuit 303 includes (n+1) comparator circuits Cr₁-Crₙ₊₁ (n is a positive integer). The comparator circuits Cr₁-Crₙ₊₁ each have four inputs. The non-inverted and inverted output voltages included in the output voltage sets from the differential amplifiers A₁-Aₘ₊₁ are input directly to the comparator circuits Cr₁-Crₙ₊₁.

The comparator circuits Cr₁-Crₙ₊₁ each have an input transistor section and a positive feedback section. Although the comparator circuit is here assumed to be formed of transistors, the comparator circuit may be formed of resistors, capacitors, and the like. The positive feedback section operates based on the clock signal CLK.

The encoder circuit 305 encodes the result of comparison (digital signal) to generate a digital data signal.

Each of the above parts will be described in detail hereinafter.

The reference voltage generation circuit 301 includes m resistors R₁-Rₘ connected together in series. A high-potential reference voltage 301a and a low-potential reference voltage 301b are applied to the opposite ends of the resistor series. As a result, a voltage between the high-potential reference voltage 301a and the low-potential reference voltage 301b is divided to generate the reference voltages VR₁-VRₘ₊₁.

The differential amplifiers A₁-Aₘ₊₁ of the differential amplifier series 302 each have two input terminals. The input analog signal voltage Ain is input to one of the two input terminals, and a corresponding one of the reference voltages VR₁-VRₘ₊₁ is input to the other input terminal. As a result, a plurality of output voltage sets (e.g., a first output voltage set, a second output voltage set, etc.) are output. Here, the output voltage sets each include a non-inverted output voltage V₁-Vₘ₊₁ and an inverted output voltage VB₁-VBₘ₊₁ which are complementary to each other.

In each of the comparator circuits Cr₁-Crₙ₊₁ of the operation circuit 303, the input transistor section performs a predetermined weighted calculation to determine a threshold voltage Vtn, compares a difference between a first non-inverted output voltage and a first inverted output voltage with a difference between a second non-inverted output voltage and a second inverted output voltage, and outputs the result of the comparison to the positive feedback section. Here, the first non-inverted output voltage and the first inverted output voltage are included in the first output voltage set, and the second non-inverted output voltage and the second inverted output voltage are included in the second output voltage set.

The positive feedback section, when the clock signal CLK is at a predetermined level, amplifies the comparison result output from the input transistor section, holds the amplified comparison result, and outputs the amplified comparison result as a digital signal to the encoder circuit 305. For example, the digital signal has a high level or a low level, depending on the comparison result.

In the first embodiment, the number of comparator circuits varies depending on the value k. Alternatively, as in the second embodiment, the number of comparator circuits may be constant regardless of the value k and may be 2^{t} (t is an integer).

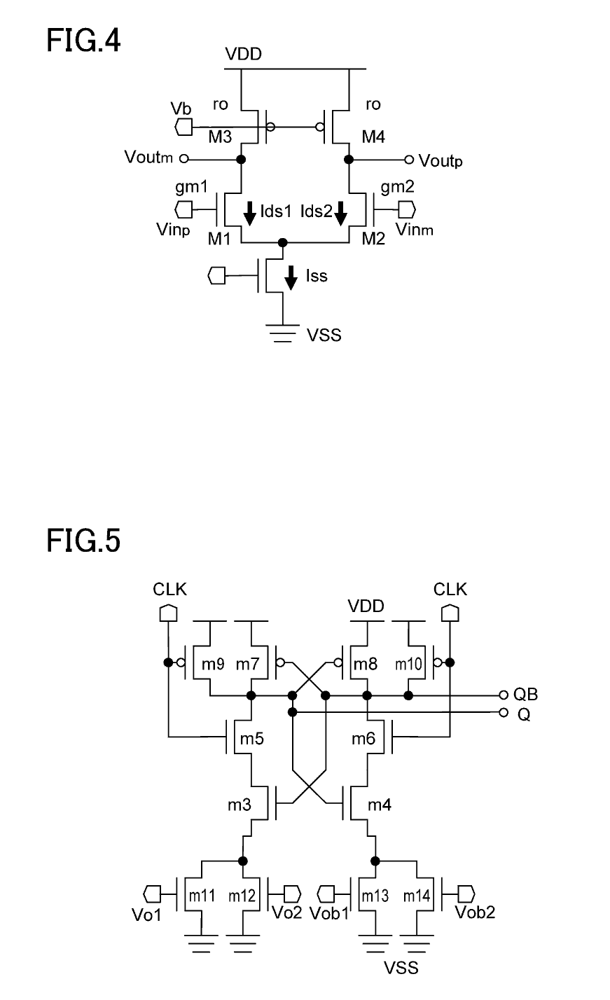

FIG. 4 shows an example circuit of the differential amplifier used in the A/D converter 300 of FIG. 3. The circuit of FIG. 4 is biased by a constant current source Iss. An analog differential input signal positive electrode Vinp and an analog differential input signal negative electrode Vinm are connected to the gate terminals of an NMOS transistor M1 and an NMOS transistor M2, respectively, which are input transistors. The gate terminals of PMOS transistors M3 and M4 are connected to a bias voltage Vb. The drain terminals of the NMOS transistor M1 and the PMOS transistor M3 are connected to an analog differential output signal negative electrode Voutm. The drain terminals of the NMOS transistor M2 and the PMOS transistor M4 are connected to an analog differential output signal positive electrode Voutp.

An analog differential input signal ΔVin=(Vinp−Vinm) is converted into a differential current ΔIds=(Ids1−Ids2) between a drain-source current Ids1 flowing through the NMOS transistor M1 and a drain-source current Ids2 flowing through the NMOS transistor M2 by the voltage-to-current conversion function of the NMOS transistors M1 and M2. The changes (ΔIds1 and ΔIds2) of the drain-source currents Ids1 and Ids2 are represented by ΔIds1=gm1(ΔVin/2) and ΔIds2=gm2(ΔVin/2), respectively, where gm1 is the transconductance of the NMOS transistor M1, and gm2 is the transconductance of the NMOS transistor M2. If it is assumed that the NMOS transistors M1 and M2 have the same characteristics, gm=gm1=gm2. An analog differential output signal ΔVout=(ΔVoutp−ΔVoutm) is represented by ΔVout=gm·ΔVin·ro, where ro is a dynamic resistance at the output end. Therefore, the voltage gain G of this circuit is represented by G=ΔVout/ΔVin=gm·ro.

In other words, the voltage gain G of the operational amplifier is in proportion to the transconductance gm of the NMOS transistors M1 and M2 (input transistors). The transconductance gm is almost in proportional to a drain-source current Ids flowing through the transistor. Therefore, in order to increase the voltage gain G, the drain-source current Ids needs to be increased. Here, for example, the drain-source current Ids can be increased by changing the size of a transistor which generates the constant current source Iss of the differential amplifier or changing the bias voltage of the transistor.

Therefore, by increasing the gains of differential amplifier circuits for an input voltage range within which analog signal components containing more important information are converted and decreasing the gains of differential amplifier circuits for an input voltage range within which analog signal components containing less important information are converted, the total power consumption of the A/D converter can be reduced.

Note that the influence of variations in the comparator circuits may be reduced by increasing the gains of differential amplifier circuits which output output voltage sets in a portion where the number of comparator circuits is large, which is described in the first embodiment.

As described above, in the second embodiment of the present disclosure, by setting the gains of differential amplifiers, depending on the value k, the circuit variation resistance is increased so that analog signal components containing more important information can be precisely converted, and the circuit variation resistance is decreased for less important information components, whereby the circuit area and power consumption can be reduced while keeping the uniformity of resolution.

Next, the comparator circuit used in the present disclosure will be described. FIG. 5 is a circuit diagram of the comparator circuit used in the A/D converter 300 of FIG. 3. The comparator circuit of FIG. 5 includes an input transistor section including NMOS transistors m11, m12, m13, and m14, and a positive feedback section (cross-coupled inverter latch section) including NMOS transistors m3 and m4 and PMOS transistors m7 and m8. Output terminals Q and QB are connected to gates in the positive feedback section. An NMOS switch transistor m5 is connected between the drain of the NMOS transistor m3 and the drain of the PMOS transistor m7, and an NMOS switch transistor m6 is connected between the drain of the MMOS transistor m4 and the drain of the PMOS transistor m8. Note that the portions where the NMOS switch transistors m5 and m6 are provided are not limited to those which are described above. Moreover, a PMOS switch transistor m9 is provided between the drain of the PMOS transistor m7 and a power supply VDD, and a PMOS switch transistor m10 is provided between the drain of the PMOS transistor m8 and the power supply VDD. The clock signal CLK is connected to the gates of the NMOS switch transistors m5 and m6 and the PMOS switch transistors m9 and m10. The NMOS transistors m11 and m12 are provided between the source of the NMOS transistor m3 and VSS. An input terminal Vo1 is connected to the gate of the NMOS transistor m11, and an input terminal Vo2 is connected to the gate of the NMOS transistor m12. The NMOS transistors m13 and m14 are provided between the source of the NMOS transistor m4 and VSS. The input terminal Vob1 is connected to the gate of the NMOS transistor m13, and an input terminal Vob2 is connected to the gate of the NMOS transistor m14.

The input transistor section performs the predetermined weighted calculation to determine the threshold voltage Vtn, compares the difference between the first non-inverted output voltage and the first inverted output voltage with the difference between the second non-inverted output voltage and the second inverted output voltage, and outputs the result of the comparison to the positive feedback section. The predetermined weighted calculation is, for example, performed by setting the ratio of the sizes of transistors in the input transistor section to a predetermined value. For example, the ratio of the sizes of the transistors m11 and m12 is set to 1:3, and the ratio of the sizes of the transistors m13 and m14 is set to 1:3, thereby obtaining the threshold voltage Vtn. Note that the predetermined weighted calculation may be performed in any other manners. For example, the predetermined weighted calculation may be performed by setting the ratio of the gate lengths or gate widths of transistors in the input transistor section to a predetermined value.

The positive feedback section, when the clock signal CLK is at a predetermined level, amplifies the comparison result output from the input transistor section, holds the amplified comparison result, and outputs the amplified comparison result as a digital signal.

Next, the drain conductances G11, G12, G13, and G14 of the NMOS transistors m11, m12, m13, and m14 are represented by:

G11=μn·Cox(W1/L)(Vo1−VT−VDS1) (1.1)

G12=μn·Cox(W2/L)(Vo2−VT−VDS1) (1.2)

G13=μn·Cox(W1/L)(Vob1−VT−VDS2) (1.3)

G14=μn·Cox(W2/L)(Vob2−VT−VDS2) (1.4)

where W1 is the gate width of the NMOS transistors m11 and m13, W2 is the gate width of the NMOS transistors m12 and m14, L is the gate length of the NMOS transistors m11, m12, m13, and m14, VT is the threshold voltage, μn is the carrier mobility, Cox is the gate capacitance, VGS1 (=Vo1), VGS2 (=Vo2), VGS3 (=Vob1), and VGS4 (=Vob2) are gate-source voltages, and VDS1 and VDS2 are drain-source voltages.

The threshold voltage of the comparator circuit of FIG. 5 is obtained when VDS1=VDS2, i.e., the sum of the drain conductance G11 of the NMOS transistor m11 and the drain conductance G12 of the NMOS transistor m12 is equal to the sum of the drain conductance G13 of the NMOS transistor m13 and the drain conductance G14 of the NMOS transistor m14. Therefore, the following equations are obtained from expressions (1.1)-(1.4).

G11+G12=G13+G14

μn·Cox·[(W1/L)(Vo1−VT−VDS1)+(W2/L)(Vo2−VT−VDS1)]=μn·Cox·[(W1/L)(Vob1−VT−VDS2)+(W2/L)(Vob2−VT−VDS2)]

Therefore,

W1·Vo1+W2·Vo2=W1·Vob1+W2·Vob2 (1.5)

If it is assumed that the ratio of the gate widths W1 and W2 is N/M:(M−N)/M, where M and N are positive integers (N<M), the following equation is obtained from expression (1.5).

[N·Vo1+(M−N)Vo2]/M=[N·Vob1+(M−N)Vob2]/M (1.6)

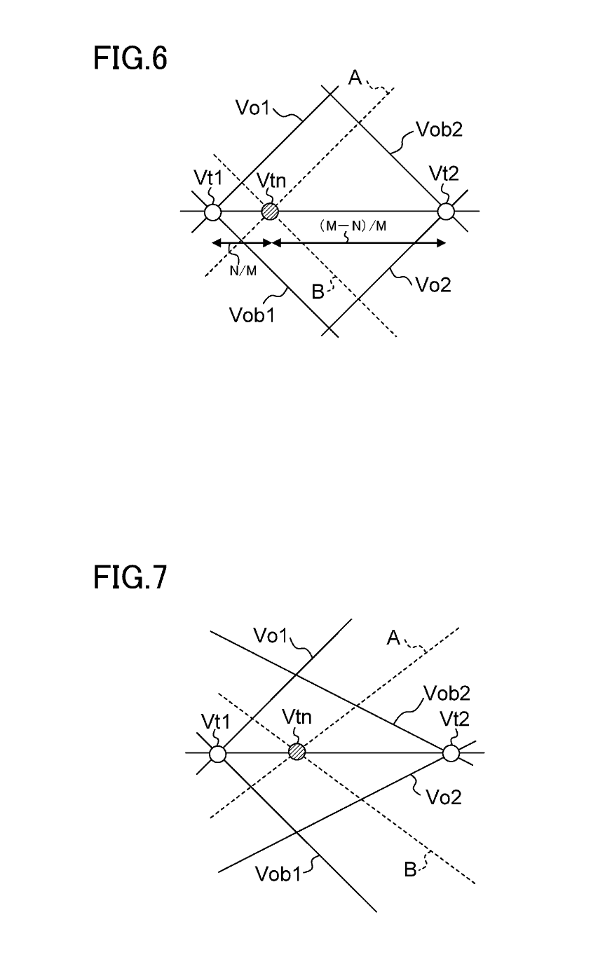

Here, expression (1.6) will be described in detail with reference to FIG. 6.

FIG. 6 is a diagram showing paths of the input signals Vo1, Vob1, Vo2, and Vob2 of the comparator circuit and the threshold. A dashed line A of FIG. 6 indicates a path of the left side of expression (1.6), which divides the input signals Vo1 and Vo2 to N:M−N. A dashed line B indicates a path of the right side of expression (1.6), which divides the input signals Vob1 and Vob2 to N:M−N. An intersection Vtn between the dashed lines A and B indicates the threshold of the comparator circuit. In this case, the intersection Vtn divides a space between an intersection Vt1 of the input signals Vo1 and Vob1 and an intersection Vt2 of the input signals Vo2 and Vob2 to N:M−N.

For example, if M=4, then when N=1, the ratio of the gate widths (W1:W2) of the NMOS transistor (m11, m13) and the NMOS transistor (m12, m14) is 1:3, so that the threshold of the comparator circuit divides the space between the intersections Vt1 and Vt2 to 1:3. When N=2, the ratio of the gate widths (W1:W2) of the NMOS transistor (m11, m13) and the NMOS transistor (m12, m14) is 2:2, so that the threshold of the comparator circuit divides the space between the intersections Vt1 and Vt2 to 2:2. When N=3, the ratio of the gate widths (W1:W2) of the NMOS transistor (m11, m13) and the NMOS transistor (m12, m14) is 3:1, so that the threshold of the comparator circuit divides the space between the intersections Vt1 and Vt2 to 3:1. Thus, by setting the ratio of the gate widths (W1:W2) of the NMOS transistor (m11, m13) and the NMOS transistor (m12, m14) to N/M:(M−N)/M, a threshold which uniformly divides the space between the intersections Vt1 and Vt2 can be obtained.

When two adjacent differential amplifiers have the same gain, input signal paths and a threshold shown in FIG. 6 are obtained. Next, input signal paths and a threshold which are obtained when two adjacent differential amplifiers have different gains are shown in FIG. 7.

As shown in FIG. 7, when two adjacent differential amplifiers have different gains, the input signal paths are horizontally asymmetric. Even in this case, by determining the transistor size ratio so that the threshold uniformly divides the space between the intersections Vt1 and Vt2, comparator circuits which correct different gains can be provided.

### Third Embodiment

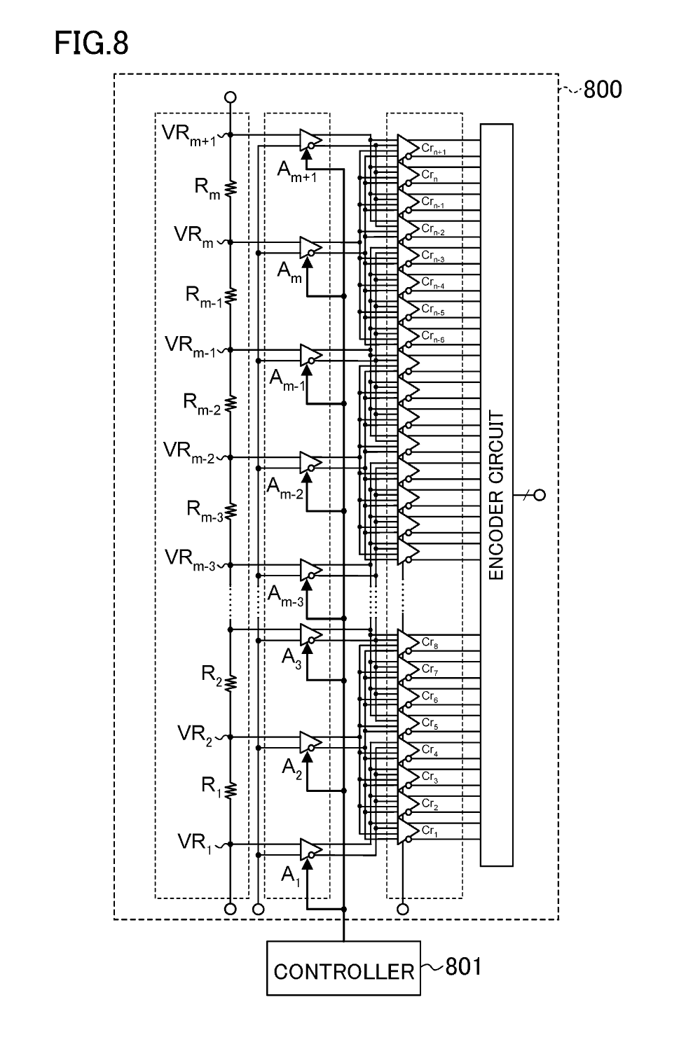

FIG. 8 is a diagram showing a configuration of an A/D converter according to a third embodiment of the present disclosure. An A/D converter body 800 of FIG. 8 is the A/D converter of the second embodiment of the present disclosure. In this embodiment, a controller 801 is provided which controls the gains of the differential amplifiers included in the A/D converter body 800, whereby the quality of a manufactured circuit can be investigated, and the amount of a current flowing through the differential amplifier circuit can be adjusted, so that the gain of each product can be optimized.

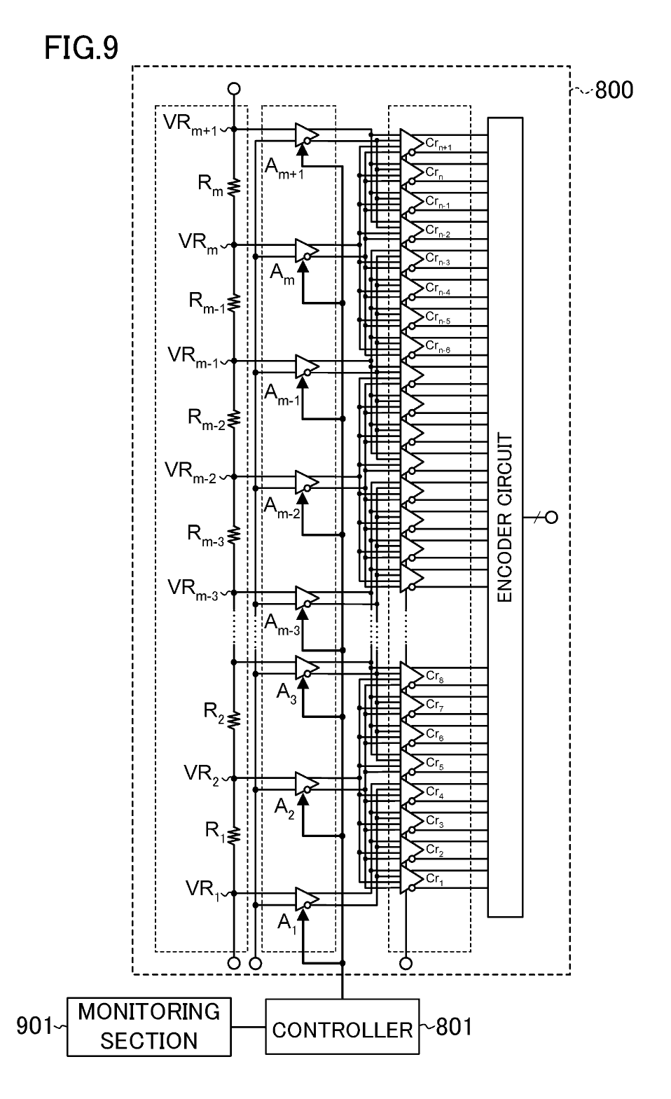

As shown in FIG. 9, a monitoring section 901 which monitors the performance of the system may be further provided. For example, if jitter output from the monitoring section 901 exceeds a threshold, the controller 801 outputs a signal for increasing the gains of the differential amplifiers in order to improve the system performance.

As described above, according to this embodiment, by optimizing the gain, taking into consideration variations in the manufacturing process, and variations in the system performance occurring in an actual use environment due to influences of signal quality, temperature, disturbance, etc., the performance of the A/D converter can be optimized, whereby power consumption can be reduced.

Note that, when higher priority is given to the reduction of the area of the controller 801, the gain of the differential amplifier can be changed by changing the transistor size. In this method, however, the gain is fixed.

### Fourth Embodiment

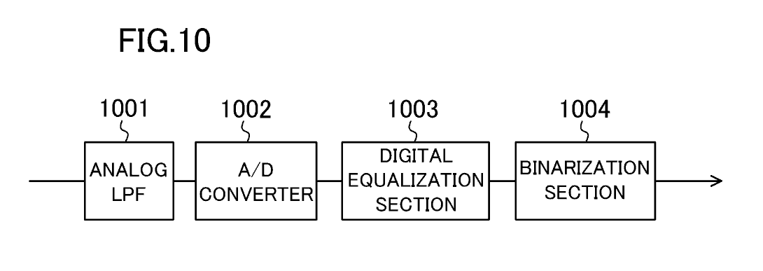

FIG. 10 is a block diagram showing a configuration of a digital equalizer according to a fourth embodiment of the present disclosure. As shown in FIG. 10, the digital equalizer includes an analog low pass filter (LPF) 1001, the A/D converter 1002 of FIG. 1, a digital equalization section 1003, and a binarization section 1004. Because the A/D converter 1002 has the configuration of FIG. 1 which more precisely converts a center portion of analog signal containing more necessary information and less precisely converts a portion of analog signal containing less necessary information, the digital equalizer can have a reduced analog circuit area and power consumption.

Also, by providing the A/D converter of FIG. 9 to a digital equalizer, the performance of the A/D converter can be changed, depending on the system performance, whereby power consumption can be reduced.

The A/D converter of the present disclosure can more precisely convert signal components of an analog signal containing more important information into a digital signal without an increase in circuit area or power consumption. Therefore, the present disclosure is useful for A/D converters which convert RF signals of information communication devices, such as hard disk devices, optical disk device, communication devices, etc.

What is claimed is:

1. A parallel interpolation A/D converter comprising:
a reference voltage generation circuit configured to generate (m+1) different reference voltages VR₁-VRₘ₊₁, where m is a positive integer, and VR₁<VR₂, . . . , <VRₘ<VRₘ₊₁;
a differential amplifier series including (m+1) differential amplifiers A₁-Aₘ₊₁ configured to amplify voltage differences between the reference voltages VR₁-VRₘ₊₁ and an input signal voltage, respectively, to generate output voltage sets, where the output voltage set of each of the differential amplifiers A₁-Aₘ₊₁ includes a non-inverted output voltage and an inverted output voltage which are complementary to each other; and
a plurality of comparator circuits configured to receive the output voltage sets of the respective differential amplifiers,
wherein
each of the comparator circuits receives a first and a second output voltage set of the plurality of output voltage sets, the first output voltage set including a first non-inverted output voltage and a first inverted output voltage and output from the differential amplifier Aₖ which receives the reference voltage VRₖ, and the second output voltage set including a second non-inverted output voltage and a second inverted output voltage and output from the differential amplifier Aₖ₋₁ which receives the reference voltage VRₖ₋₁, where k is an integer of 2≦k≦m+1, compares a difference of the first output voltage set with a difference of the second output voltage set, and based on a result of the comparison, outputs a digital signal, and
the number of the comparator circuits varies depending on the value k of the reference voltage VRₖ.

2. A parallel interpolation A/D converter comprising:
a reference voltage generation circuit configured to generate (m+1) different reference voltages VR₁-VRₘ₊₁, where m is a positive integer, and VR₁<VR₂, . . . , <VRₘ<VRₘ₊₁;
a differential amplifier series including (m+1) differential amplifiers A₁-Aₘ₊₁ configured to amplify voltage differences between the reference voltages VR₁-VRₘ₊₁ and an input signal voltage, respectively, to generate output voltage sets, where the output voltage set of each of the differential amplifiers A₁-Aₘ₊₁ includes a non-inverted output voltage and an inverted output voltage which are complementary to each other; and
a plurality of comparator circuits configured to receive the output voltage sets of the respective differential amplifiers,
wherein
each of the comparator circuits receives a first and a second output voltage set of the plurality of output voltage sets, the first output voltage set including a first non-inverted output voltage and a first inverted output voltage and output from the differential amplifier Aₖ which receives the reference voltage VRₖ, and the second output voltage set including a second non-inverted output voltage and a second inverted output voltage and output from the differential amplifier Aₖ₋₁ which receives the reference voltage VRₖ₋₁, where k is an integer of 2≦k≦m+1, compares a difference of the first output voltage set with a difference of the second output voltage set, and based on a result of the comparison, outputs a digital signal, and
the differential amplifiers have different gains.

3. The parallel interpolation A/D converter of claim 2, wherein
the comparator circuits correct the gains of the differential amplifiers.

4. The parallel interpolation A/D converter of claim 2, further comprising:
a controller configured to control the gains of the differential amplifiers.

5. The parallel interpolation A/D converter of claim 4, further comprising:
a monitoring section configured to monitor system performance,
wherein
the gains of the differential amplifiers are controlled based on information from the monitoring section.

6. The parallel interpolation A/D converter of claim 2, wherein
the gain of each of the differential amplifiers is determined by a size of a transistor included in each of the differential amplifiers.

7. A digital equalizer comprising:
the parallel interpolation A/D converter of claim 1 configured to convert an analog signal into a digital signal; and
a digital equalization section configured to perform waveform equalization on the digital signal output from the parallel interpolation A/D converter.

8. A digital equalizer comprising:
the parallel interpolation A/D converter of claim 2 configured to convert an analog signal into a digital signal; and
a digital equalization section configured to perform waveform equalization on the digital signal output from the parallel interpolation A/D converter.
